(19) United States
(12) Patent Application Publication
(10) Pub. No.: US 2025/0096058 A1
(43) Pub. Date: Mar. 20, 2025

(54) STAIR-STEP CONFIGURATION FOR A SEMICONDUCTOR DIE OF AN INTEGRATED CIRCUIT

(71) Applicant: Western Digital Technologies, Inc., San Jose, CA (US)

(72) Inventors: Huoliang Chen, Shanghai (CN); Weiting Jiang, Shanghai (CN); Fan Ye, Shanghai (CN); Yihao Chen, Shanghai (CN)

(21) Appl. No.: 18/468,904

(22) Filed: Sep. 18, 2023

(51) Int. Cl. H01L 23/31; H01L 21/78; H01L 23/00; H01L 29/06

(52) U.S. Cl. CPC H01L 23/3157; H01L 21/78; H01L 24/16; H01L 24/32; H01L 24/73; H01L 24/92; H10D 62/117; H01L 2224/16227; H01L 2224/32225; H01L 2224/73204; H01L 2224/92125

(57) ABSTRACT

A semiconductor die, such as a flip-chip die, has a stairstep configuration, which reduces or eliminates the risk of an occurrence of an epoxy on die phenomenon. The stairstep configuration of the semiconductor die is formed during a multi-cut wafer dicing process associated with a semiconductor die fabrication process. During the multi-cut wafer dicing process, a first cutting device, having a first width, forms a first cut in the wafer. The first cut extends partially through the wafer. A second cutting device, having a second width, forms a second cut within the first cut. The combination of the first cut and the second cut form the stairstep configuration of the semiconductor die.

### BACKGROUND

An integrated circuit typically includes multiple semiconductor dies. In some configurations, at least one of the semiconductor dies is a flip-chip die. The flip-chip die is coupled to a substrate of the integrated circuit using one or more bumps. When the flip-chip die is coupled to the substrate, an underfill material is applied to the substrate to fill any gaps between the flip-chip die and the substrate. The underfill material also provides mechanical reinforcement and thermal conductivity thereby increasing the reliability and performance of the integrated circuit.

However, when the underfill material is applied, some of the underfill material may climb to, or otherwise be dispensed on, a top surface of the flip-chip die. This is referred to as the “epoxy on die” phenomenon. If additional semiconductor dies are stacked on top of the flip-chip die, the epoxy on die area may cause the additional semiconductor dies to crack.

Accordingly, it would be beneficial for a flip-chip die to have features that prevent the epoxy on die phenomenon from occurring.

### SUMMARY

The present application describes an integrated circuit that includes a semiconductor die having a stairstep configuration. In an example, the semiconductor die is a flip-chip die and the stairstep configuration helps prevent an underfill material from reaching a top surface of the semiconductor die during an integrated circuit assembly process.

The stairstep configuration of the semiconductor die may be formed during a multi-cut wafer dicing process associated with a semiconductor die fabrication process. For example, during the multi-cut wafer dicing process, a first cutting device, having a first width, forms a first cut in a wafer on which the semiconductor die is fabricated. In an example, the first cut partially extends through the wafer. When the first cut has been formed, a second cutting device, having a second width, forms a second cut in the wafer. In an example, the second cut is formed within the first cut, thereby forming the stairstep configuration.

When the semiconductor die is attached to a substrate of the integrated circuit, an underfill material may be dispensed on the substrate. However, the stairstep configuration of the semiconductor die will prevent the underfill material from climbing up and/or over the side of the semiconductor die, thereby eliminating the risk of the epoxy on die phenomenon.

Accordingly, examples of the present disclosure describe an integrated circuit that includes a semiconductor die. The semiconductor die has a first surface and a second surface opposite the first surface. The semiconductor die also includes a third surface disposed between the first surface and the second surface such that the semiconductor die has a stairstep configuration. A plurality of connection points may extend from the first surface of the semiconductor die. In an example, the plurality of connection points communicatively couple the semiconductor die to a substrate of the integrated circuit.

Examples of the present disclosure also describe a method that includes obtaining a wafer including a first semiconductor die and a second semiconductor die. A first cut is formed on the wafer between the first semiconductor die and the second semiconductor die. In an example, the first cut is formed by a first cutting device having a first width. Additionally, the first cut partially extends through the wafer. A second cut may then be formed in the wafer between the first semiconductor die and the second semiconductor die. In an example, the second cut is formed by a second cutting device having a second width that is narrower than the first width. Additionally, the first cut and the second cut form a stairstep configuration between the first semiconductor die and the second semiconductor die.

Other examples of the present disclosure describe an integrated circuit having a semiconductor die. In an example the semiconductor die has a first surface, a second surface opposite the first surface and a third surface disposed between the first surface and the second surface. The third surface may be formed from a first cutting means having a first width and a second cutting means having a second width. In an example, the first cutting means forms a first cut partially though a wafer associated with the semiconductor die and the second cutting means forms a second cut within the first cut such that the semiconductor die has a stairstep configuration.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates an integrated circuit having a multiple semiconductor dies according to current solutions.

FIG. 2 illustrates an integrated circuit having a semiconductor die with a stairstep configuration according to an example.

FIG. 3A illustrates a first cutting device forming a first cut in a wafer on which multiple semiconductor dies have been fabricated according to an example.

FIG. 3B illustrates the wafer of FIG. 3A once the first cut has been formed according to an example.

FIG. 3C illustrates a second cutting device forming a second cut in the wafer of FIG. 3B according to an example.

FIG. 3D illustrates the wafer of FIG. 3C once the second cut has been formed according to an example.

FIG. 4 illustrates a semiconductor die having multiple surfaces arranged in a stairstep configuration according to an example.

FIG. 5 illustrates a method for assembling an integrated circuit according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As used herein, the term “integrated circuit” refers to a package comprising one or more semiconductor dies attached and electrically connected to a printed circuit board or substrate and encapsulated with a protective material, such as an epoxy mold compound. For example, an integrated circuit may include a flip-chip die that is coupled to a substrate of the integrated circuit. When the flip-chip die is mounted to the substrate, an underfill material is typically applied between the flip-chip die and the substrate. The underfill material is used to fill any gaps between the flip-chip die and the substrate. The underfill material also provides mechanical reinforcement to the semiconductor die and increases the reliability of the integrated circuit as a whole.

However, during an underfill material dispensing process, some of the underfill material may climb up a sidewall of the flip-chip die or otherwise be dispensed on a top surface of the flip-chip die. As previously explained, this is referred to as the epoxy on die phenomenon. The epoxy on die area on the top surface of the flip-chip die can negatively affect the performance of the integrated circuit. For example, if additional semiconductor dies (e.g., memory dies) are stacked on top of the flip-chip die, the epoxy on die area may cause stress on the additional semiconductor dies. The additional stress may cause one or more of the additional semiconductor dies to crack.

In examples in which the additional semiconductor dies are memory dies, one or more bond wires may couple the memory dies to the substrate. The bond wires may add additional pressure which may increase the risk of cracking. Additionally, if the integrated circuit includes a molding compound that encapsulates the various semiconductor dies, the molding compound may further increase the pressure on the epoxy on die area, which may further increase the risk of cracking.

To address the above, the present application describes an integrated circuit that includes a semiconductor die having a stairstep configuration. In an example, the semiconductor die is a flip-chip die and the stairstep configuration helps control the dispersion of underfill material and/or prevent the underfill material from climbing to a top surface of the semiconductor die.

The stairstep configuration of the semiconductor die may be formed during a multi-cut wafer dicing process associated with a semiconductor die fabrication process. For example, during the multi-cut wafer dicing process, a first cutting device having a first width forms a first cut in a wafer on which the semiconductor die is fabricated. In an example, the first cut partially extends through the wafer. When the first cut has been formed in the wafer, a second cutting device having a second width forms a second cut in the wafer. In an example, the second cut is formed within the first cut, thereby forming the stairstep configuration.

When the semiconductor die is attached to a substrate of the integrated circuit and an underfill material is applied, the stairstep configuration of the semiconductor die prevents the underfill material from climbing up and/or over the side of the semiconductor die.

Accordingly, many technical benefits may be realized including, but not limited to, substantially reducing or eliminating the epoxy on die phenomenon; maintaining or reducing a Z-height requirement of an integrated circuit by maintaining or reducing a Z-height of one or more semiconductor dies of the integrated circuit; and increasing the reliability of integrated circuits.

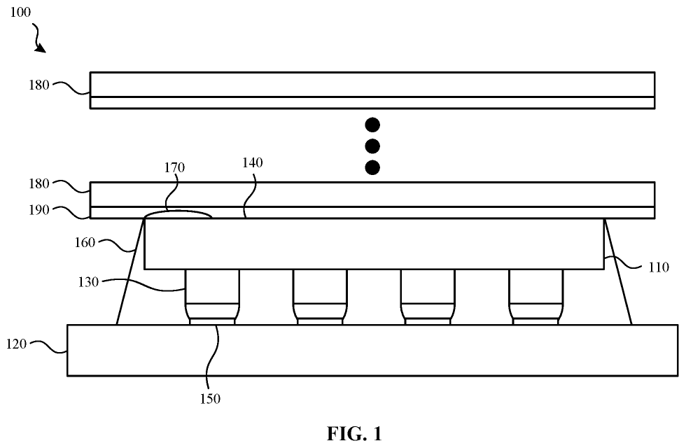

These and other examples will be shown and described in greater detail with respect to FIG. 1-FIG. 5.

FIG. 1 illustrates an integrated circuit 100 having a multiple semiconductor dies according to current solutions. In the example shown, the integrated circuit 100 includes a first semiconductor die 110 coupled to a substrate 120. In this example, the first semiconductor die 110 is a flip-chip die. As such, a plurality of bumps 130 may extend from a bottom surface of the semiconductor die 110. The bumps 130 are electrically coupled to corresponding pads 150 on the substrate 120.

When the semiconductor die 110 has been coupled to the substrate 120, an underfill material 160 (typically an epoxy) is applied to the substrate 120. As previously indicated, the underfill material 160 is applied to the substrate 120 to fill any gaps between the semiconductor die 110 and the substrate 120. However, when the underfill material 160 is applied to the substrate 120, some of the underfill material 160 may inadvertently be dispensed on a top surface 140 of the semiconductor die 110. In another example, once the underfill material 160 has been dispensed, some of the underfill material 160 may climb up a sidewall of the semiconductor die 110 and be disposed on the top surface 140 of the semiconductor die 110. This is shown in FIG. 1 as an epoxy on die area 170.

The epoxy on die area 170 may cause issues for the integrated circuit 100. For example, the integrated circuit 100 may include one or more additional semiconductor dies 180. Each of these semiconductor dies 180 may be stacked on the top surface 140 of the semiconductor die 110 using an adhesive 190. If the epoxy on die area 170 is thicker than the adhesive 190, the epoxy on die area 170 may cause additional stress on one or more of the additional semiconductor dies 180. The additional stress may cause one of more of the additional semiconductor dies 180 to crack. The stress on the one or more additional semiconductor dies 180 may increase as various connection points (e.g., bond wires) are added to the integrated circuit 100 and/or if a molding compound is used to encapsulate the various semiconductor dies.

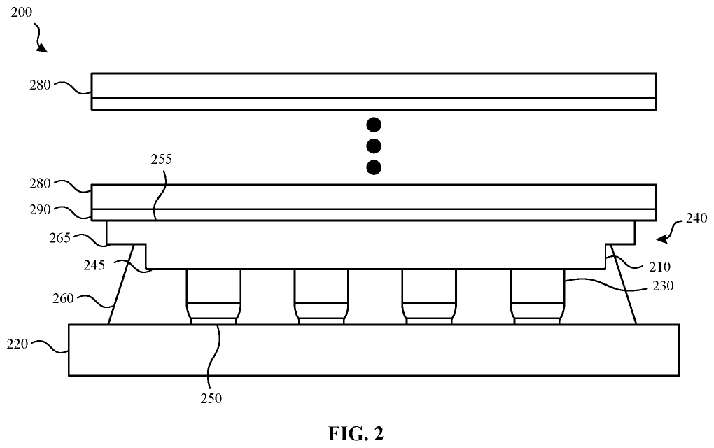

FIG. 2 illustrates an integrated circuit 200 having a semiconductor die 210 with a stairstep configuration 240 according to an example. The stairstep configuration 240 of the semiconductor die 210 substantially reduces or eliminates the risk of the occurrence of the epoxy on die phenomenon.

The semiconductor die 210 of the integrated circuit 200 may be coupled to a substrate 220. In an example, the semiconductor die 210 is a flip-chip die. In an example, the semiconductor die 210 may have a height of one hundred micrometers (μm). Although one hundred μm is specifically mentioned, the semiconductor die 210 may have a height greater than one hundred μm or less than one hundred μm.

The semiconductor die 210 has a first surface 245, a second surface 255 and a third surface 265. The third surface 265 is positioned or otherwise provided between the first surface 245 and the second surface 255. The first surface 245, the second surface 255 and the third surface 265 may form the stairstep configuration 240. For example, the first surface 245 may have a first width from a first side of the semiconductor die 210 to a second side of the semiconductor die 210. The second surface 255 may have a second width from the first side of the semiconductor die 210 to the second side of the semiconductor die 210.

The third surface 265 may have a third width that is less than the first width and the second width. For example, the third surface 265 may be formed or otherwise defined by a first sidewall that extends from a distal end of the first surface 245 and a second sidewall that extends from a distal end of the second surface 255. The third surface 265 may extend between the first sidewall and the second sidewall and form a “step” shape of the stairstep configuration 240. The step shape may be formed on one or more sides of the semiconductor die 210.

In an example, the third surface 265 (or the step shape) is formed during a multi-cut wafer dicing process associated with a semiconductor die fabrication process in which the semiconductor die 210 is fabricated. For example, during a first phase of the multi-cut wafer dicing process, a first cutting device forms a first cut in a wafer on which the semiconductor die 210 is fabricated. The first cutting device has a first width. In an example, the first cut extends partially through the wafer.

During a second phase of the multi-cut wafer dicing process, a second cutting device forms a second cut on the wafer. In an example, the second cut is formed within the first cut. The second cutting device may have a second width that is different from the first width of the first cutting device. For example, the second width is narrower/smaller when compared to the first width.

In an example, the second cutting device forms the second cut in the wafer such that the second cut extends through the remaining portion of the wafer (e.g., the portion of the wafer that was not cut by the first cutting device). However, in another example, the second cutting device forms the second cut partially through the remaining portion of the wafer. In such an example, a third cutting device may form a third cut in the wafer. For example, a third cutting device, having a third width, may form the third cut within the second cut. The third cut may extend through the remaining portion of the wafer (e.g., the portion of the wafer that was not cut by either the first cutting device and/or the second cutting device).

In an example, at least one of the first cutting device and the second cutting device is a saw (e.g., a wafer saw). In another example, at least one of the first cutting device and the second cutting device is a laser. Although a saw and a laser are specifically mentioned, other cutting devices may be used.

As previously mentioned, the semiconductor die 210 may be a flip-chip die. As such, a plurality of bumps 230 may extend from the second surface 245 of the semiconductor die 210. The bumps 230 may be electrically coupled to corresponding pads 250 on the substrate 220.

The integrated circuit 200 may also include an underfill material 260. The underfill material 260 may be applied to, or otherwise dispensed on, the substrate 220 before or after the semiconductor die 210 is mounted to the substrate 220. However, unlike the example shown in FIG. 1 in which the underfill material 160 has climbed up the side of the semiconductor die 110 and formed the epoxy on die area 170, the stairstep configuration 240 of the semiconductor die 210 prevents the underfill material 260 from reaching the second surface 255 of the semiconductor die 210. For example, although the underfill material 260 may reach the third surface 265 of the stairstep configuration 240, the underfill material 260 cannot reach the second surface 255 due to a combination of gravity, surface tension and/or the step shape associated with the third surface 265.

The integrated circuit 200 may also include one or more additional semiconductor dies 280. In an example, at least one of the additional semiconductor dies 280 is coupled to the second surface 255 of the semiconductor die 240 using an adhesive 290. In an example, the additional semiconductor dies 280 are memory dies (e.g., NAND memory dies). Although memory dies are specifically mentioned, the additional semiconductor dies 280 may be any type of semiconductor die.

In addition to preventing the underfill material 260 from reaching the second surface 255 of the semiconductor die 210, the stairstep configuration 240 may also reduce or eliminate the need for a keep-out area on the top surface of the semiconductor die 210. For example and referring back to FIG. 1, a keep-out area is associated with the epoxy on die area 170. The keep-out area is an area that should be avoided when stacking the one or more additional semiconductor dies 180 on the semiconductor die 110.

For example, in order to avoid the epoxy on die area 170, the one or more additional semiconductor dies 180 may be moved to the right (or to the left) a particular distance in order to avoid being stacked on the epoxy on die area 170. In some examples, the keep-out area may be three hundred micrometers (μm) or more. However, some integrated circuits 100 may not have enough space in an X/Y direction to avoid the keep-out area.

Referring back to FIG. 2 and as previously explained, the stairstep configuration 240 prevents the epoxy on die phenomenon from occurring. As such, one or more of the additional semiconductor dies 280 may be stacked at any location on the top surface of the semiconductor die 210.

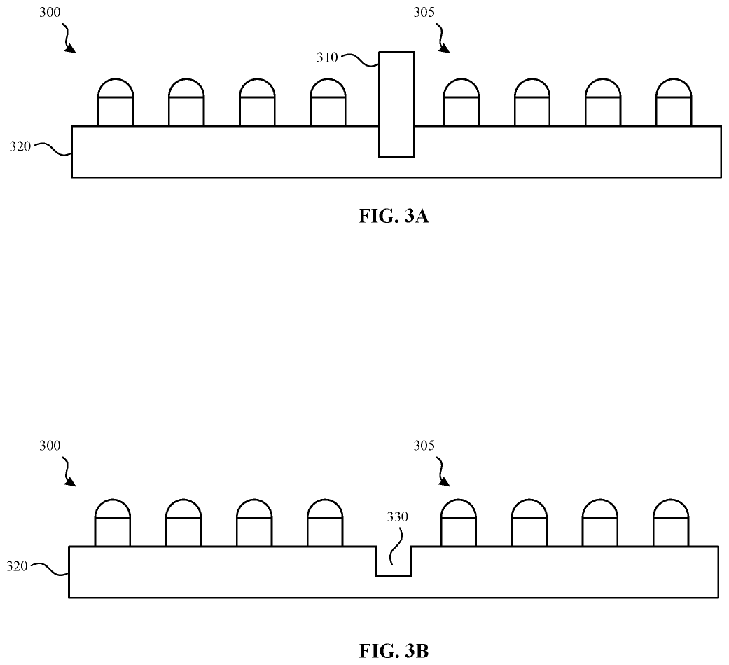

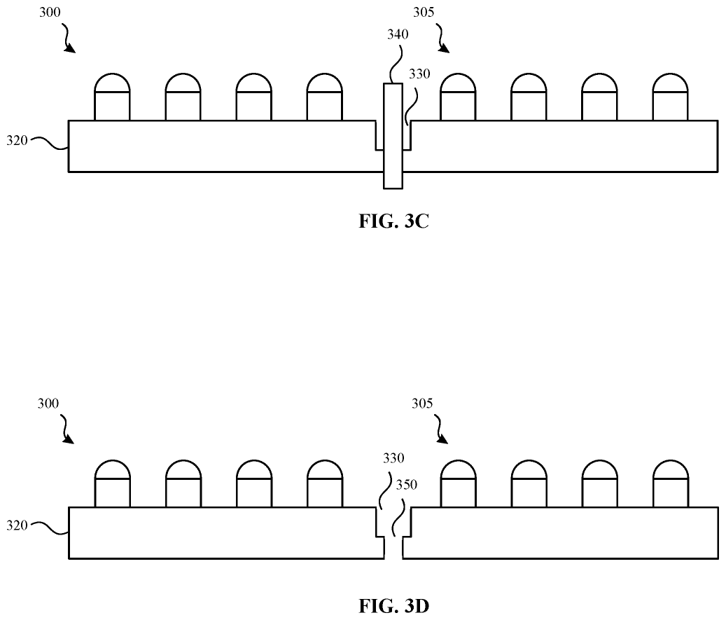

FIG. 3A illustrates a first cutting device 310 forming a first cut in a wafer 320 on which multiple semiconductor dies have been fabricated according to an example. In an example, a first semiconductor die 300 and a second semiconductor die 305 may be fabricated on, or otherwise associated with, the wafer 320. Each of the first semiconductor die 300 and the second semiconductor die 305 may be similar to the semiconductor die 210 shown and described with respect to FIG. 2.

In an example, the first cutting device 310 forms the first cut in the wafer 320 between the first semiconductor die 300 and the second semiconductor die 305. The first cutting device 310 may be a saw. In another example, the first cutting device 310 is a laser. Regardless of the type of the first cutting device 310, the first cutting device 310 has a first width. In an example, the first width may range between fifty μm and one hundred μm. Although a specific range is mentioned, the first cutting device 310 may have any width.

FIG. 3B illustrates the wafer 320 of FIG. 3A once the first cut 330 has been formed according to an example. As shown in FIG. 3B, the first cut 330 extends partially through the wafer 320. In an example, a height of a sidewall of the step shape (e.g., a height of a first sidewall associated with the third surface 245 of the semiconductor die 210 (FIG. 2)) is based, at least in part, on a depth of the first cut 330. In some examples, the first cut 330 may extend fifty μm through the wafer 320. Although fifty μm is specifically mentioned, the depth may be less than fifty μm or more than fifty μm. FIG. 3C illustrates a second cutting device 340 forming a second cut in the wafer 320 of FIG. 3B according to an example. In this example, the second cutting device 340 forms the second cut within the first cut 330. For example, the second cutting device 340 may be positioned in a middle or center of the first cut 330 and in between the first semiconductor die 300 and the second semiconductor die 305.

In an example, the second cutting device 340 is a saw. In another example, the second cutting device 340 is laser. In yet another example, a stealth dicing process may be used to form the second cut. Regardless of the type of the second cutting device 340, the second cutting device 340 has a second width that is less than the first width. In an example, the second width may range between twenty μm and eighty μm. Although a specific range is mentioned, the second cutting device 340 may have any width.

In an example, the width of the second cutting device 340, in addition to the width of the first cutting device 310, impacts a size/width of the step shape (e.g., the third surface 245 of the semiconductor die 240 (FIG. 2)). For example, if the first cutting device 310 has a width of X and the second cutting 340 device has a width of Y, a width of the step shape formed in the wafer 320 would be (X−Y)/2.

FIG. 3D illustrates the wafer 320 of FIG. 3C once the second cut 350 has been formed according to an example. As shown in FIG. 3D, the second cut 350 is formed within the first cut 330. Additionally, the second cut 350 extends through the remaining portion of the wafer 320 (e.g., the portion of the wafer 320 that was not cut by the first cutting device 310).

In an example, a height of another sidewall of the step shape (e.g., a height of a second sidewall associated with the third surface 245 of the semiconductor die 240 (FIG. 2)) is based, at least in part, on a depth of the first cut 330 with respect to a depth of the second cut 350.

Although two cutting devices are mentioned with respect to FIG. 3A-FIG. 3D, any number of cutting devices may be used to form additional steps in the wafer 320.

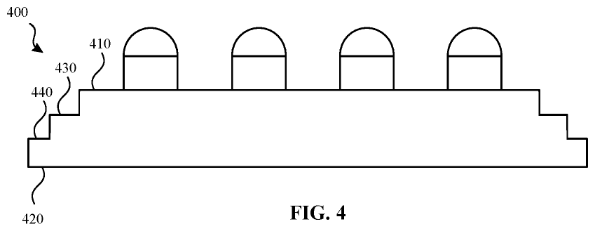

FIG. 4 illustrates a semiconductor die 400 having multiple surfaces arranged in a stairstep configuration according to an example. In an example, the semiconductor die 400 is a flip-chip die and may be included in an integrated circuit such as, for example, the integrated circuit 200 shown and described with respect to FIG. 2. The semiconductor die 400 includes a first surface 410, a second surface 420, a third surface 430 and a fourth surface 440.

Each of the third surface 430 and the fourth surface 440 (and sidewalls associated with each of the third surface 430 and the fourth surface 440) may be formed during a multi-cut wafer dicing process such as previously described. However, instead of two cutting devices being used, the multiple steps/surfaces of the semiconductor die 400 are formed using three (or more) cutting device.

Although FIG. 3D and FIG. 4 show semiconductor dies having a specified number of steps and/or surfaces, it is contemplated that a semiconductor die may have any number of steps/surfaces. Additionally, each step/surface may be formed as a results of one or more cutting devices forming one or more cuts in a wafer of the semiconductor die. Each of the one or more cuts may have a same width/depth or a different width/depth.

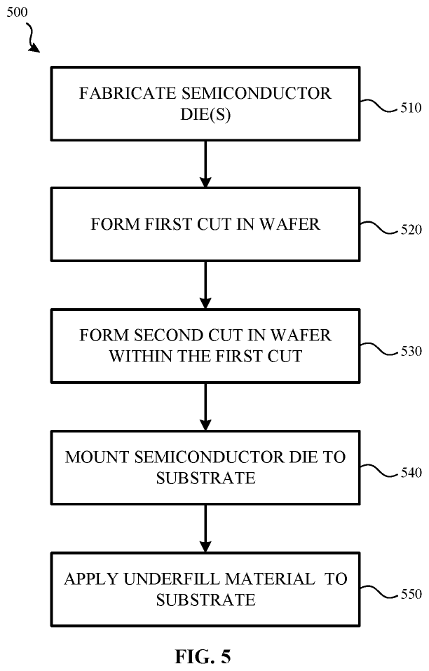

FIG. 5 illustrates a method 500 for assembling an integrated circuit according to an example. In an example, the method 500 may be used to assemble the integrated circuit 200 shown and describe with respect to FIG. 2.

Method 500 begins when one or more semiconductor dies are fabricated (510). In an example, any suitable fabrication technique may be used. For example, various components of the one or more semiconductor dies may be fabricated on a wafer. In another example, a wafer including a first semiconductor die and a second semiconductor die may be obtained.

When the semiconductor dies have been fabricated and/or obtained, a first cut is formed (520) in the wafer. In an example, the first cut is formed by a first cutting device having a first width. The first cut may extend partially through the wafer.

When the first cut has been formed, a second cutting device forms (530) a second cut in the wafer. In an example, the second cut is formed within the first cut. Additionally, the second cutting device may have a second width that is less than the first width of the first cutting device. The second cutting device may cut through the remaining portion of the wafer (e.g., the portion of the wafer that was not cut by the first cutting device). As a result, a semiconductor die having a stairstep configuration may be separated from the wafer.

Once the semiconductor die has been separated from the wafer, the semiconductor die may be mounted (540) to a substrate of the integrated circuit. In an example, the semiconductor die is a flip-chip die. As such, one or more bumps on a surface of the semiconductor die may be electrically coupled to corresponding pads on the substrate.

An underfill material may then be applied (550) to the substrate. As previously indicated, the stairstep configuration of the semiconductor die will reduce or eliminate the risk of the epoxy on die phenomenon occurring when the underfill material is applied to the substrate.

Examples of the present disclosure describe an integrated circuit, comprising: a semiconductor die having a first surface, a second surface opposite the first surface, and a third surface disposed between the first surface and the second surface such that the semiconductor die has a stairstep configuration; and a plurality of connection points extending from the first surface of the semiconductor die, the plurality of connection points communicatively coupling the integrated circuit to a substrate of the integrated circuit. In an example, the integrated circuit also includes an underfill material provided between the first surface of the semiconductor die and the substrate. In an example, the stairstep configuration of the semiconductor die prevents the underfill material from reaching the second surface of the semiconductor die. In an example, the semiconductor die is a first semiconductor die and wherein the integrated circuit further comprises a second semiconductor die coupled to the second surface of the first semiconductor die. In an example, the second semiconductor die is a memory die. In an example, the stairstep configuration is formed during a multi-cut wafer dicing process in which: a first cut is made using a first cutting device having a first width; and a second cut is made using a second cutting device having second width. In an example, at least one of the first cutting device and the second cutting device is a saw. In an example, at least one of the first cutting device and the second cutting device is a laser. In an example, the first cut extends a first depth through a wafer associated with the integrated circuit and the second cut extents a second depth through the wafer associated with the integrated circuit.

Examples of the present disclosure also describe a method, comprising: obtaining a wafer including a first semiconductor die and a second semiconductor die; fabricating a first semiconductor die and a second semiconductor die on a wafer; forming a first cut in the wafer between the first semiconductor die and the second semiconductor die, wherein the first cut is formed by a first cutting device having a first width and wherein the first cut partially extends through the wafer; and forming a second cut in the wafer between the first semiconductor die and the second semiconductor die, wherein the second cut is formed by a second cutting device having a second width that is narrower than the first width and wherein the first cut and the second cut form a stairstep configuration between the first semiconductor die and the second semiconductor die. In an example, the second cut extends through the wafer. In an example, the method also includes forming a third cut in the wafer between the first semiconductor die and the second semiconductor die, wherein the third cut is formed by a third cutting device having a third width that is narrower than the first width and the second width. In an example, at least one of the first cutting device and the second cutting device is a saw. In an example, at least one of the first cutting device and the second cutting device is a laser. In an example, the method also includes coupling the first semiconductor die to a substrate of an integrated circuit; and dispensing an underfill material between the first semiconductor die and the substrate, wherein the stairstep configuration associated with the first semiconductor die prevents the underfill material from reaching a top surface of the first semiconductor die.

Examples of the present disclosure also describe an integrated circuit, comprising: a semiconductor die having: a first surface; a second surface opposite the first surface; and a third surface disposed between the first surface and the second surface, wherein the third surface is formed from a first cutting means having a first width and a second cutting means having a second width, wherein the first cutting means forms a first cut partially though a wafer associated with the semiconductor die and wherein the second cutting means forms a second cut within the first cut such that the semiconductor die has a stairstep configuration. In an example, the integrated circuit also includes a plurality of connection means extending from the first surface of the semiconductor die, the plurality of connection means communicatively coupling the semiconductor die to a substrate of the integrated circuit. In an example, the stairstep configuration of the semiconductor die prevents an underfill material from reaching the second surface of the semiconductor die when the underfill material is applied to the substrate. In an example, at least one of the first cutting means and the second cutting means is a saw. In an example, at least one of the first cutting means and the second cutting means is a laser.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An integrated circuit, comprising:
a semiconductor die having a first surface, a second surface opposite the first surface, and a third surface disposed between the first surface and the second surface such that the semiconductor die has a stairstep configuration; and
a plurality of connection points extending from the first surface of the semiconductor die, the plurality of connection points communicatively coupling the integrated circuit to a substrate of the integrated circuit.

2. The integrated circuit of claim 1, further comprising an underfill material provided between the first surface of the semiconductor die and the substrate.

3. The integrated circuit of claim 2, wherein the stairstep configuration of the semiconductor die prevents the underfill material from reaching the second surface of the semiconductor die.

4. The integrated circuit of claim 1, wherein the semiconductor die is a first semiconductor die and wherein the integrated circuit further comprises a second semiconductor die coupled to the second surface of the first semiconductor die.

5. The integrated circuit of claim 4, wherein the second semiconductor die is a memory die.

6. The integrated circuit of claim 1, wherein the stairstep configuration is formed during a multi-cut wafer dicing process in which:
a first cut is made using a first cutting device having a first width; and
a second cut is made using a second cutting device having second width.

7. The integrated circuit of claim 6, wherein at least one of the first cutting device and the second cutting device is a saw.

8. The integrated circuit of claim 6, wherein at least one of the first cutting device and the second cutting device is a laser.

9. The integrated circuit of claim 6, wherein the first cut extends a first depth through a wafer associated with the integrated circuit and the second cut extents a second depth through the wafer associated with the integrated circuit.

10. A method, comprising:
obtaining a wafer including a first semiconductor die and a second semiconductor die on a wafer;
forming a first cut in the wafer between the first semiconductor die and the second semiconductor die, wherein the first cut is formed by a first cutting device having a first width and wherein the first cut partially extends through the wafer; and
forming a second cut in the wafer between the first semiconductor die and the second semiconductor die, wherein the second cut is formed by a second cutting device having a second width that is narrower than the first width and wherein the first cut and the second cut form a stairstep configuration between the first semiconductor die and the second semiconductor die.

11. The method of claim 10, wherein the second cut extends through the wafer.

12. The method of claim 10, further comprising forming a third cut in the wafer between the first semiconductor die and the second semiconductor die, wherein the third cut is formed by a third cutting device having a third width that is narrower than the first width and the second width.

13. The method of claim 10, wherein at least one of the first cutting device and the second cutting device is a saw.

14. The method of claim 10, wherein at least one of the first cutting device and the second cutting device is a laser.

15. The method of claim 10, further comprising:
coupling the first semiconductor die to a substrate of an integrated circuit; and
dispensing an underfill material between the first semiconductor die and the substrate, wherein the stairstep configuration associated with the first semiconductor die prevents the underfill material from reaching a top surface of the first semiconductor die.

16. An integrated circuit, comprising:
a semiconductor die having:
a first surface;
a second surface opposite the first surface; and
a third surface disposed between the first surface and the second surface, wherein the third surface is formed from a first cutting means having a first width and a second cutting means having a second width, wherein the first cutting means forms a first cut partially though a wafer associated with the semiconductor die and wherein the second cutting means forms a second cut within the first cut such that the semiconductor die has a stairstep configuration.

17. The integrated circuit of claim 16, further comprising a plurality of connection means extending from the first surface of the semiconductor die, the plurality of connection means communicatively coupling the semiconductor die to a substrate of the integrated circuit.

18. The integrated circuit of claim 17, wherein the stairstep configuration of the semiconductor die prevents an underfill material from reaching the second surface of the semiconductor die when the underfill material is applied to the substrate.

19. The integrated circuit of claim 16, wherein at least one of the first cutting means and the second cutting means is a saw.

20. The integrated circuit of claim 16, wherein at least one of the first cutting means and the second cutting means is a laser.
